(19) United States
(12) Patent Application Publication
(10) Pub. No.: US 2022/0272860 A1
(43) Pub. Date: Aug. 25, 2022

(54) STORAGE DEVICE MODULE FOR SERVER

(71) Applicants: Inventec (Pudong) Technology Corporation, Shanghai (CN); INVENTEC CORPORATION, Taipei (TW)

(72) Inventor: Shuai Zhang, Shanghai (CN)

(21) Appl. No.: 17/204,025

(22) Filed: Mar. 17, 2021

(30) Foreign Application Priority Data
Feb. 20, 2021 (CN) 202110194009.0

(51) Int. Cl. H05K 7/14

(52) U.S. Cl. CPC H05K 7/1488; H05K 7/1438

(57) ABSTRACT

A storage device module for a server includes a rack, a backplane and at least one storage device assembly. The rack has an opening and an accommodation space connected to the opening, wherein the accommodation space includes at least one recess for 2.5-inch storage device. The backplane is fixed to the rack and located on an opposite side of the opening. The at least one storage device assembly includes a carrier and two ruler SSDs, wherein the carrier is removably disposed in the at least one recess. The carrier is insertable into the at least one recess through the opening and removable from the at least one recess through the opening, the ruler SSDs are disposed on the carrier, and the ruler SSDs are electrically connected to the backplane.

### CROSS-REFERENCE TO RELATED APPLICATIONS

This non-provisional application claims priority under 35 U.S.C. § 119(a) on Patent Application No(s). 202110194009.0 filed in China on Feb. 20, 2021, the entire contents of which are hereby incorporated by reference.

### BACKGROUND

### 1. Technical Field

This disclosure relates to a storage device module, especially to a storage device module for a server.

### 2. Related Art

With the coming of the internet era, a variety of technology and device developments related to the internet are growing flourishly. The storage technology of data is gradually changing with the growing of needs, and thereby developing various ways of data storage, such as compact disc, hard drive and solid state drive.

Generally speaking, a storage device is disposed on a storage device carrier before being installed into a server, and the storage device carrier with the storage device is then disposed in the storage rack. Conventionally, when a storage device in the server is replaced with another type, the original carrier and the rack for the storage device usually have to be removed and replaced with another carrier and rack for another type of storage device; alternately, if the original storage rack is not to be replaced with another one, the another type of storage device usually needs to be disposed on a carrier and then be put into a compatible shell, so that it can be installed in the original storage rack, thereby increasing the overall costs when the users replace or upgrade devices of servers.

### SUMMARY

Accordingly, the present disclosure provides a storage device module for server, which is capable of solving the problem of the prior art in which when storage devices in the server are replaced with another types, both the carrier and the rack have to be replaced or via a plurality of additional shells served as compatible interfaces in order to be disposed on the original rack, thereby increasing the overall costs when the users replace or upgrade devices of servers.

According to one or more embodiment of the disclosure, a storage device module for a server includes: a rack having an opening and an accommodation space connected to the opening, wherein the accommodation space includes at least one recess for 2.5-inch storage device; a backplane fixed to the rack and located on an opposite side of the opening; and at least one storage device assembly including a carrier and two ruler SSDs, wherein the carrier is removably disposed in the at least one recess, the carrier is insertable into the at least one recess through the opening and removable from the at least one recess through the opening, the ruler SSDs are disposed on the carrier, and the ruler SSDs are electrically connected to the backplane.

In view of the storage device module for server disclosed in the above description, by designing a storage device assembly having two ruler SSDs to be capable of fitting in a recess for a 2.5-inch storage drive, the replacement of storage device of the server under the same structure can be more convenient, and the versatility of the storage rack originally designed for a 2.5-inch storage drive is achieved and thereby reducing the overall costs when the users replace or upgrade devices of servers.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a perspective view of a server and a storage device module thereof according to one embodiment of the present disclosure;

FIG. 2 is a partial exploded view of the storage device module in FIG. 1;

FIG. 3 is another perspective view of a rack and a backplane in FIG. 1;

FIG. 4 is an exploded view of the rack and the backplane in FIG. 3;

FIG. 5 is an exploded view of one of the storage device assemblies in FIG. 1; and

FIGS. 6 and 7 show the operation processes of one of the storage device assemblies in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

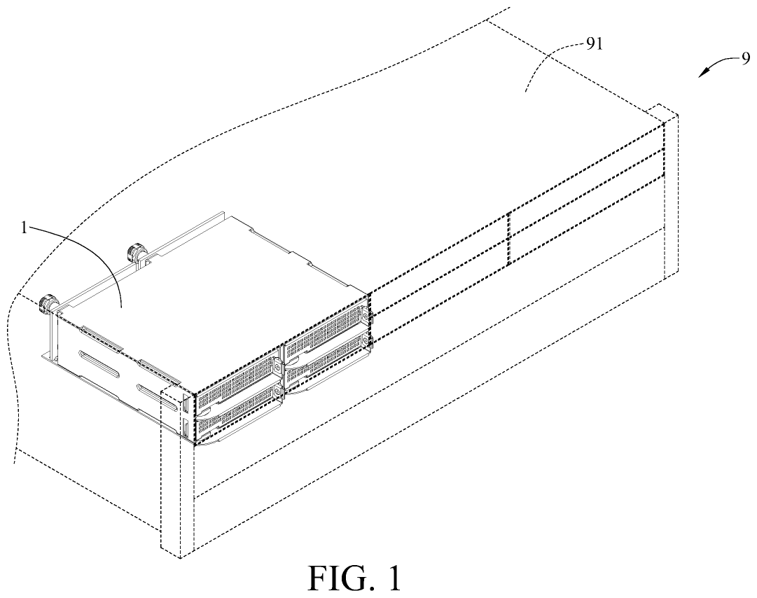

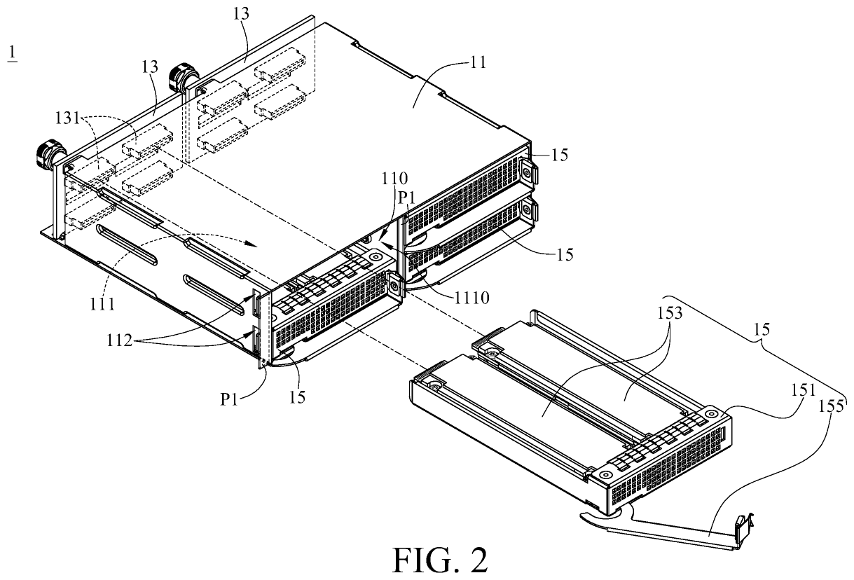

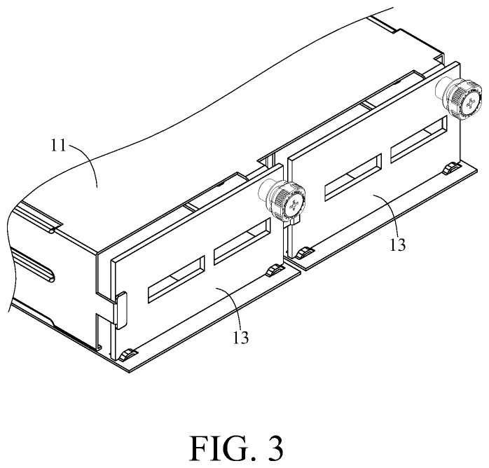

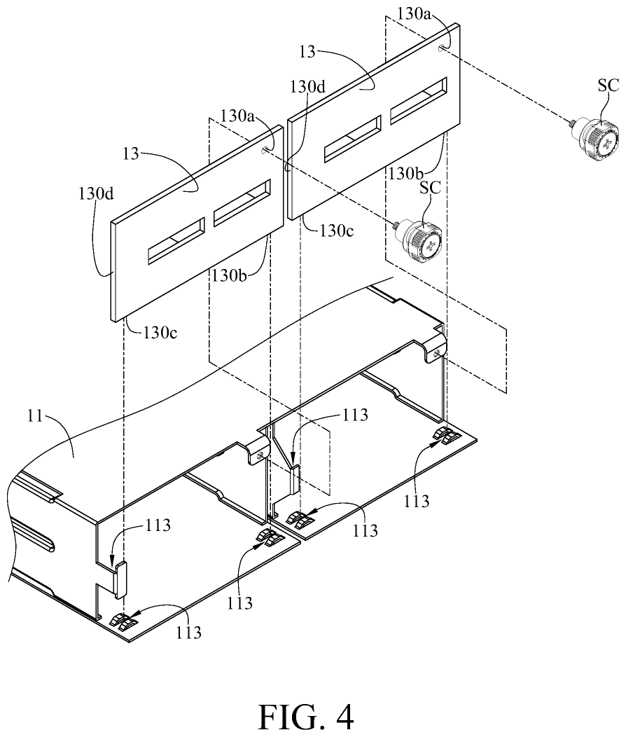

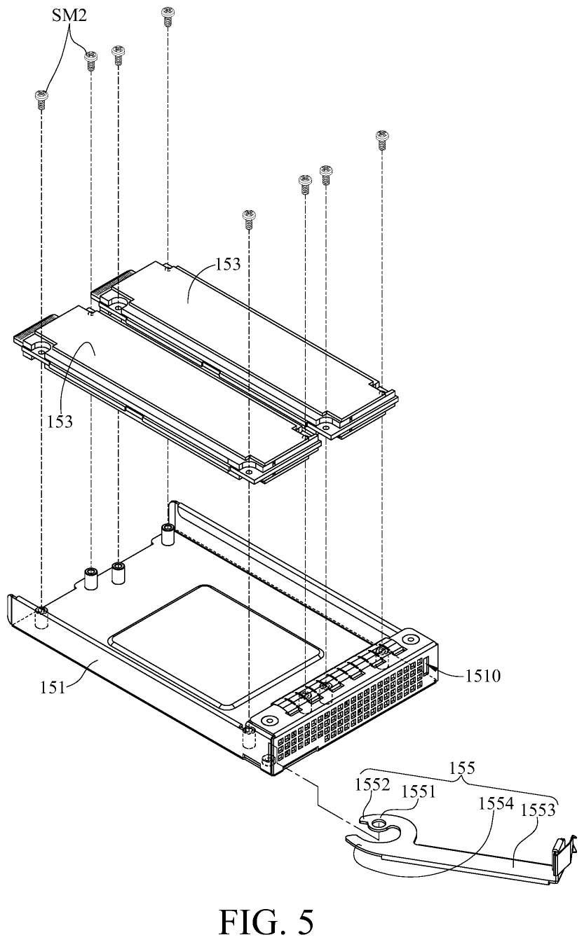

Please refer to FIG. 1 to FIG. 5, wherein FIG. 1 is a perspective view of a server and a storage device module thereof according to one embodiment of the present disclosure, FIG. 2 is a partial exploded view of the storage device module in FIG. 1, FIG. 3 is another perspective view of a rack and a backplane in FIG. 1, FIG. 4 is an exploded view of the rack and the backplane in FIG. 3, and FIG. 5 is an exploded view of one of the storage device assemblies in FIG. 1.

In this embodiment, a server 9 is provided. The server 9 includes a storage device module 1 and a case 91. The storage device module 1 is disposed on the case 91. The storage device module 1 includes a rack 11, two backplanes 13 and four storage device assemblies 15.

The rack 11 is disposed on the case 91 of the server 9. The rack 11 has an opening 110, four snap holes 112 and an accommodation space 111 connected to the opening 110. The accommodation space 111 includes four recesses 1110 for 2.5-inch storage device, and the four snap holes 112 respectively and correspondingly located on one side of the four recess 1110. In this embodiment, the rack 11 is designed for four 2.5-inch storage devices to be disposed therein, and the 2.5-inch storage devices may be 2.5-inch hard disk drives or 2.5-inch solid state drives. In specific, the rack 11 is designed to have the four recesses 1110, and the size of each of the recesses 1110 matches the size of a carrier for one 2.5- inch storage device to be disposed thereon, so that each of the recesses 1110 is configured for a carrier for one 2.5-inch storage device or a component having substantially the same size of the carrier to be disposed therein. However, the present disclosure is not limit to the configuration of the rack 11 above. In other embodiments, the accommodation space of the rack may include different quantity of recesses for a corresponding quantity of storage devices and carriers thereof to be disposed therein.

The backplanes 13 are fixed to the rack 11 and located at the opposite side of the opening 110 of the rack 11. Each of the backplanes 13 has four fixing parts 130a, 130b, 130c and 130d configured to fix the backplanes 13 to the rack 11, and any three of those fixing parts 130a, 130b, 130c and 130d are not collinear. Specifically, as shown in FIG. 4, each of the fixing parts 130a includes a screw hole, and the backplane 13 may be fixed to the rack 11 by a quick release screw SC screwed through the screw hole of the fixing part 130a. Besides, the rest three fixing parts 130b, 130c and 130d are respectively located at two adjacent edges of the backplane 13 and are configured to be engaged with three engagement grooves 113 of the rack 11.

The four storage device assemblies 15 are respectively removably disposed in the four recesses 1110 of the rack 11. Each of the four storage device assemblies 15 includes a carrier 151, two ruler solid state drives (SSDs) 153 and a fastener 155. The quantity of the ruler SSDs in each of the storage device assemblies 15 is two. The appearance of said ruler SSD is similar to a ruler, which is different from the plain appearance of conventional 2.5-inch and 3.5-inch hard drive, PCIe interface card, M.2/U.2 solid state drive, or the like. More precisely, the ruler SSD includes two form factor of Enterprise and Data Center SSD Form Factor (EDSFF) 1U long and EDSFF 1U short. Generally speaking, the length of the EDSFF 1U long is 319 mm and the width is 38 mm, and the length of the EDSFF 1U short is 112 mm and the width is 32 mm. There are two types of the EDSFF 1U long having difference thicknesses of 9.5 mm and 18 mm, and the thickness of the EDSFF 1U short may be 6 mm to 8 mm. Besides, the capacity of a single EDSFF 1U long ruler SSD may be 8 TB to 64 TB, and the capacity of a single EDSFF 1U short ruler SSD may be 4 TB to 8 TB, so that the capacity provided by the ruler SSDs under the 1U structure may be 1 PB which is way larger than the capacity of the conventional 2.5-inch and 3.5-inch storage device. Usually, a server in a standard 1U structure may accommodate 32 EDSFF 1U long ruler SSDs.

The carrier 151 is insertable into the recess 1110 through the opening 110, and is removable from the recess 1110 through the opening 110.

The ruler SSDs 153 are disposed on the carrier 151, and the ruler SSDs 153 are inserted into the slots 131 of the backplane 13 and electrically connected to the backplane 13. Each of the ruler SSDs 153 has a length, a width and a height, wherein the length is larger than the width and the width is larger than the height. In this embodiment, the two ruler SSDs 153 of each of the storage device assemblies 15 are disposed in parallel in the widthwise direction on the carrier 151. In addition, in this embodiment, every ruler SSD 153 is fixed to the carrier 151 by four M2 screws SM2, but the present disclosure is not limited thereto. In other embodiments, the ruler SSDs may be fixed to the carrier via other fixing means such as fixing plugs.

In this embodiment, the four storage device assemblies 15 are disposed in the accommodation space 111 in an arrangement of two columns and two rows.

In the storage device module 1 for the server 9 disclosed by the present disclosure, there is no other shell or shelf located between the carrier 151 and the ruler SSD 153 of the storage device assembly 15 and there is no other shell or shelf located between the carrier 151 and the rack 11. In other words, the ruler SSD 153 does not require other shell or shelf served as a compatible interface to be installed on the carrier 151, and the carrier 151 does not require other shell or shelf served as a compatible interface to be installed on the rack 11, either, so that the ruler SSD 153 can be installed into the rack 11 merely through the carrier 151 served as a single compatible interface.

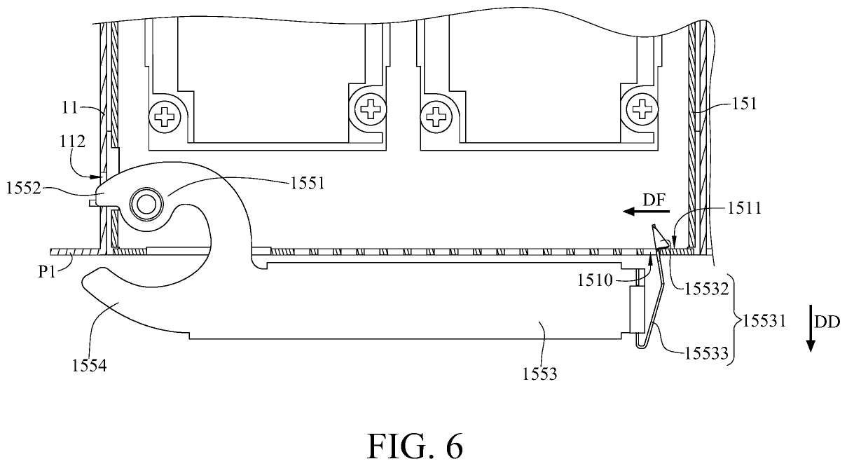

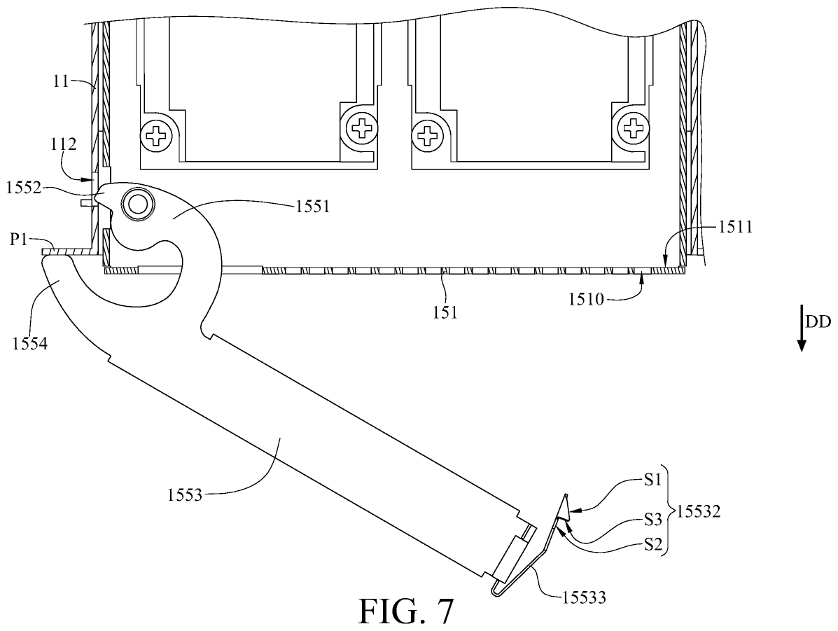

Please refer to FIG. 6 and FIG. 7, which show the operation processes of one of the storage device assemblies in FIG. 1.

The fastener 155 includes a pivot part 1551, a hook part 1552, an operation part 1553 and a pushing part 1554. The pivot part 1551 is pivotally coupled to one side of the carrier 151, wherein the one side is exposed by the opening 110 of the rack 11. The hook part 1552 and the operation part 1553 are respectively connected to two sides of the pivot part 1551, wherein the hook part 1552 is removably disposed through the snap hole 112 of the rack 11, and the operation part 1553 is removably engaged with the carrier 151 so as to fix the carrier 151 in the recess 1110.

When the storage device assembly 15 is to be removed from the rack 11, the operation part 1553 may be detachable from the carrier 151 by an external force such that the fastener 155 is pivotable from a fastened position (as shown in FIG. 6) to an unlock position (as shown in FIG. 7) by an external force. When the fastener 155 is pivoted from the fastened position to the unlock position, the hook part 1552 is detached from the snap hole 112, thereby making the carrier 151 movable relative to the rack 11 and removable from the rack 11 along a drawing direction DD.

Specifically, the operation part 1553 has a spring leaf 15531, and the spring leaf 15531 includes an engaging part 15532 and an elastic part 15533. The engaging part 15532 is removably disposed through a fixing hole 1510 located at one side of the carrier 151 exposed by the opening 110, and the engaging part 15532 is abutted against an interior surface 1511 of the carrier 151 so as to fix the operation part 1553 to the carrier 151. Besides, the elastic part 15533 is movable from a snap position to an unsnap position along a force direction DF by an external force. When the elastic part 15533 is moved from the snap position to the unsnap position along the force direction DF, the engaging part 15532 is moved along with the elastic part 15533, and thus the engaging part 15532 is spaced apart from the interior surface 1511 and removable from the fixing hole 1510 to the exterior, so that the operation part 1553 can be detached from the carrier 151, thereby making the fastener 155 pivotable relative to the carrier 151.

On the other hand, when the storage device assembly 15 is to be disposed back into the recess 1110 of the rack 11, the carrier 151 is firstly inserted into the recess 1110 along a direction opposite to the drawing direction DD, and then the fastener 155 is pivoted from the unlock position (as shown in FIG. 7) to the fastened position (as shown in FIG. 6), such that the hook part 1552 is disposed through the snap hole 112, making the operation part 1553 engaged with the carrier 151, and the assembling of the storage device assembly 15 is completed.

Specifically, the engaging part 15532 of the spring leaf 15531 has a leaning surface S1, a holding surface S2 and a limit surface S3. The leaning surface S1 is configured to be abutted against on a wall surrounding the fixing hole 1510 in a process of the engaging part 15532 being inserted into the fixing hole 1510 of the rack 11 from the exterior, so that the elastic part 15533 gradually deforms along the force direction DF and stores an elastic deforming force. When the engaging part 15532 passes through the fixing hole 1510 and is spaced apart from the wall surrounding the fixing hole 1510, the elastic part 15533 releases the elastic deforming force, and the elastic part 15533 reinstates back in its original position along the direction opposite to the force direction DF, making the holding surface S2 abutted against the wall surrounding the fixing hole 1510, and such that the interior surface 1511 of the carrier 151 blocks the limit surface S3 so as to limit a displacement of the operation part 1553, wherein a direction of the displacement points away from the fixing hole 1510. The direction of the operation part 1553 facing away from the fixing hole 1510 is substantially the same as the drawing direction DD.

The pushing part 1554 of the fastener 155 is connected to the pivot part 1551 and is located at one side opposite to the operation part 1553. The pushing part 1554 corresponds to a holding plate P1 of the rack 11. When the fastener 155 is pivoted from the fastened position (as shown in FIG. 6) to the unlock position (as shown in FIG. 7), the pushing part 1554 presses against the holding plate P1 of the rack 11 and is thereby being a fulcrum when the storage device assembly 15 is being removed.

In view of the storage device module for server disclosed in the above embodiment, by designing a storage device assembly having two ruler SSDs to be capable of fitting in a recess for a 2.5-inch storage drive, the replacement of the storage device of the server under the same structure can be more convenient, increasing the versatility of the storage rack originally for 2.5-inch storage drive and thereby reducing the overall costs when the users replace or upgrade devices of servers.

In addition, by designing the structure of the carrier with two ruler SSDs and the corresponding backplane to be similar to a structure of carrier for conventional 2.5-inch storage device and the corresponding backplane, the rack originally provided for 2.5-inch storage device can be compatible with the carrier with two ruler SSDs, and the original design of fixing structure may be fully applied, thereby assuring the overall mechanical strength of the storage device module while satisfying easy-changing and cost saving at the same time. Besides, the backplane is designed to be capable of engaging in the engaging grooves of the rack in advance, and is then screwed to the rack through the quick release screw at one point, which is beneficial to the storage device module replacement efficiency.

Besides, there is no other shell or shelf between the carrier of the storage device assembly and the ruler SSD, and there is no other shell or shelf between the carrier and the rack. In other words, the ruler SSD does not require other shell or shelf served as a compatible interface to be disposed on the carrier, and the carrier does not require other shell or shelf served as a compatible interface to be disposed on the rack, either, so that the ruler SSD may be disposed on the rack merely through the carrier served as a single compatible interface. Accordingly, the overall costs when the users replace or upgrade devices of the servers may be reduced.

Moreover, the storage device assembly includes a fastener which can be operated without a hand tool and is respectively engaged and fixed to the rack and the carrier through the hook part and the operation part connected to two sides of the pivot part, such that the storage device assembly can be fixed in the recess; on the other hand, by unlocking the spring leaf of the operation part to pivot the fastener and thereby making the hook part detached from the snap hole of the rack, the carrier is removable from the rack. Accordingly, the removing and the assembling without a hand tool may be achieved.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A storage device module for a server comprising:
a rack having an opening and an accommodation space connected to the opening, wherein the accommodation space comprises at least one recess for 2.5- inch storage device;
a backplane fixed to the rack and located on an opposite side of the opening; and
at least one storage device assembly comprising a carrier and two ruler SSDs, wherein the carrier is removably disposed in the at least one recess, the carrier is insertable into the at least one recess through the opening and removable from the at least one recess through the opening, the ruler SSDs are disposed on the carrier, and the ruler SSDs are electrically connected to the backplane.

2. The storage device module of claim 1, wherein no shell or shelf is disposed between the carrier and the ruler SSDs of the at least one storage device assembly, and no shell or shelf is disposed between the carrier and the rack.

3. The storage device module of claim 1, wherein the quantity of the at least one recess is four, the quantity of the at least one storage device assembly is four, the quantity of the ruler SSDs of each of the storage device assemblies is two, the four storage device assemblies are respectively and removably disposed in the four recesses, and the four storage device assemblies are in an arrangement of two-columns and two- rows in the accommodation space.

4. The storage device module of claim 1, wherein each of the ruler SSDs has a length, a width and a height, the length is larger than the width, the width is larger than the height, and the ruler SSDs are arranged in parallel in a widthwise direction in the carrier.

5. The storage device module of claim 1, wherein the at least one storage device assembly further comprises a fastener, the rack further has at least one snap hole, the fastener comprises a pivot part and a hook part and an operation part respectively connected to two sides of the pivot part, the pivot part is pivotally coupled to one side of the carrier wherein the one side is exposed by the opening of the rack, the hook part is removably disposed through the at least one snap hole to fix the carrier in the at least one recess, the operation part is removably engaged with the carrier, the operation part is detachable from the carrier by an external force, such that the fastener is pivotable from a fastened position to an unlock position by an external force; when the fastener is pivoted from the fastened position to the unlock position, the hook part is detached from the snap hole, thereby making the carrier movable relative to the rack.

6. The storage device module of claim 5, wherein the carrier has a fixing hole at one side thereof wherein the one side is exposed by the opening of the rack, the operation part has a spring leaf, the spring leaf comprises an engaging part and an elastic part, the engaging part is removably disposed through the fixing hole and abutted against an interior surface of the carrier to fix the operation part to the carrier, the elastic part is movable from a snap position to an unsnap position by an external force; when the elastic part is moved from the snap position to the unsnap position, the engaging part is moved along with the elastic part and thus spaced apart from the interior surface so as to be removable from the fixing hole to outside, so that the operation part is detached from the carrier, thereby making the fastener pivotable relative to the carrier.

7. The storage device module of claim 6, wherein the engaging part has a leaning surface, a holding surface and a limit surface, the leaning surface is configured to be abutted against on a wall surrounding the fixing hole in a process of the engaging part being inserted into the fixing hole from exterior, so that the elastic part gradually deforms and stores an elastic deforming force; when the engaging part passes through the fixing hole and the leaning surface is spaced apart from the wall surrounding the fixing hole, the elastic part releases the elastic deforming force, making the holding surface abutted against the wall surrounding the fixing hole, such that the interior surface of the carrier blocks the limit surface so as to limit a displacement of the operation part, wherein a direction of the displacement points away from the fixing hole.

8. The storage device module of claim 5, wherein the fastener further comprises a pushing part, the pushing part is connected to the pivot part and located at one side opposite to the operation part, and the pushing part corresponds to the rack; when the fastener is pivoted from the fastened position to the unlock position, the pushing part pushes the rack and is thereby being a fulcrum when removing the at least one storage device assembly.

9. The storage device module of claim 1, wherein the backplane has four fixing parts configured to fix the backplane to the rack, and any three of the four fixing parts are not collinear.

10. The storage device module of claim 9, wherein one of the fixing parts of the backplane is screwed to the rack through a quick release screw, and rest of the fixing parts are engaged with three engagement grooves of the rack.
